(19) United States
(12) Patent Application Publication
(10) Pub. No.: US 2020/0068711 A1
(43) Pub. Date: Feb. 27, 2020

(54) COMPONENT TERMINATIONS FOR SEMICONDUCTOR PACKAGES

(71) Applicant: Intel IP Corporation, Santa Clara, CA (US)

(72) Inventors: Andreas Wolter, Regensburg (DE); Georg Seidemann, Landshut (DE); Klaus Reingruber, Langquaid (DE); Thomas Wagner, Regelsbach (DE)

(21) Appl. No.: 16/343,961

(22) PCT Filed: Nov. 23, 2016
(86) PCT No.: PCT/US16/63583

§ 371 Date: Apr. 22, 2019

(51) Int. Cl. H05K 1/11; H05K 1/18; H01L 23/00; H05K 3/34

(52) U.S. Cl. CPC H05K 1/114; H05K 1/185; H01L 24/03; H01L 2224/04105; H05K 3/3484; H01L 2224/02371; H01L 24/05

(57) ABSTRACT

Systems and methods are provide to form one or more pads on at least one surface associated with a portion of a component, for example, a component associated with a surface-mounted device (SMD). Further, the systems and methods are directed to providing metal (for example, copper, Cu) layers on the surface of one or more terminations (for example, solder termination pads) of an electrical component. In one embodiment, the metal layers include metal termination pads that are fabricated on a carrier layer; components can be soldered to these termination pads, then the components with the metal pads can be debonded from the carrier layer. As such, the solder terminations of the components can be covered by the metal pads.

The disclosed systems and methods can permit or otherwise facilitate a wider selection and easy availability of the components to be electrically and/or mechanically connected to semiconductor packages.

### TECHNICAL FIELD

This disclosure generally relates to systems and methods directed to component terminations, for example, component terminations used in connection with semiconductor packages.

### BACKGROUND

Microelectronics packaging, including, for example, system in a package (SIP), system on a package (SOP), package on package (PoP), and 3D stacked package, can refer to systems that may integrate one or more dies/chips and various components into a semiconductor package. Example components may include, but not be limited to, passive elements, filters, switches, microelectromechanical systems (MEMSs) sensors, and the like. These components may further include solder-coated terminations that can be used for mounting surface-mounted devices (SMDs).

### BRIEF DESCRIPTION OF THE FIGURES

Reference will now be made to the accompanying drawings, which are not necessarily drawn to scale, and wherein:

FIGS. 1A-1B illustrate a diagram of an embedded wafer level ball grid array (also referred to as EWLB or eWLB herein) package, in accordance with one or more embodiments of this disclosure.

FIGS. 2A-2G illustrate example diagrams of various structures produced by an example processing sequence for the formation of one or more metal pads (for example, Cu pads) on at least one surface associated with a solder termination member of a component, for example, a component associated with a surface-mounted device (SMD), in accordance with the one or more embodiments of the disclosure.

FIGS. 3A-3F illustrate example diagrams of various structures produced by an alternative example processing sequence for the formation of one or more metal pads (for example, Cu pads) on at least one surface associated with a solder termination member of a component, for example, a component associated with an SMD, in accordance with the one or more embodiments of the disclosure.

FIGS. 4A-4H illustrate example diagrams of various structures produced by an alternative example processing sequence for the formation of one or more metal pads (for example, Cu pads) on at least one surface associated with a solder termination member of a component, for example, a component associated with an SMD, in accordance with the one or more embodiments of the disclosure.

FIGS. 5A-5D illustrate example diagrams of various structures produced by an alternative example processing sequence for the formation of one or more metal pads (for example, Cu pads) on at least one surface associated with a solder termination member of a component, for example, a component associated with an SMD, in accordance with the one or more embodiments of the disclosure.

FIGS. 6A-6B illustrate example methods for fabricating the formation of one or more metal pads (for example, Cu pads) on at least one surface associated with a solder termination member of a component, for example, a component associated with an SMD, in accordance with embodiments of the disclosure.

FIG. 7 illustrates an example of a system in accordance with one or more embodiments of the disclosure.

### DETAILED DESCRIPTION

Embodiments of the disclosure are described more fully hereinafter with reference to the accompanying drawings, in which example embodiments of the disclosure are shown. This disclosure may, however, be embodied in many different forms and should not be construed as limited to the example embodiments set forth herein; rather, these embodiments are provided so this disclosure will be thorough and complete and will fully convey the scope of the disclosure to those skilled in the art. Like numbers refer to like but not necessarily the same or identical elements throughout.

The following embodiments are described in sufficient detail to enable at least those skilled in the art to understand and use this disclosure. It is to be understood that other embodiments would be evident based on the present disclosure and that process, mechanical, material, dimensional, process equipment, and parametric changes may be made without departing from the scope of the present disclosure.

In the following description, numerous specific details are given to provide a thorough understanding of various embodiments of this disclosure. However, it will be apparent that this disclosure may be practiced without these specific details. In order to avoid obscuring the present disclosure, some well-known system configurations and processing steps may not be disclosed in full detail. Likewise, the drawings showing embodiments of this disclosure are semi-diagrammatic and not to scale and, particularly, some of the dimensions are for the clarity of presentation and may be exaggerated in the drawings. In addition, where multiple embodiments are disclosed and described as having some features in common, for clarity and ease of illustration, description, and comprehension thereof, similar and like features will ordinarily be described with like reference numerals even if the features are not identical.

The term “horizontal” as used herein may be defined as a direction parallel to a plane or surface (for example, surface of a substrate) regardless of its orientation. The term “vertical” as used herein may refer to a direction orthogonal to the horizontal direction as just described. Terms such as “on,” “above,” “below,” “bottom,” “top,” “side” (as in “sidewall”), “higher,” “lower,” “upper,” “over,” and “under” may be referenced with respect to the horizontal plane. The term “processing” as used herein includes deposition of material or photoresist, patterning, exposure, development, etching, cleaning, ablating, polishing, and/or removal of the material or photoresist as required in forming a described structure.

ASIP (system in a package) may integrate dies/chips and various types of electronic components into a package, for example, a semiconductor package. Further, many package technologies use redistribution layers (RDLs). RDLs can refer to metal and dielectric layers that can be added to wafers and/or dies for routing electrical signals. However, some approaches in RDL processing may not be suitable for making contact to embedded components with solder terminations, due to reliability problems at the interface between a portion of the RDL and a solder termination, for example, a solder termination of components associated with various electronic components.

Disclosed herein, among other things, are systems and methods directed to providing metal (for example, copper, Cu) layers on the surface of one or more terminations (for example, solder termination pads) of an electrical component and/or connector. In one embodiment, the metal layers include metal termination pads that are fabricated on a carrier layer; components can be soldered to these termination pads, then the components with the metal pads can be debonded from the carrier layer. Thus, the solder terminations of the components can be covered by the metal pads. Further, contact to these metal pads can be made, for example, using one or more RDL-processing methods/techniques.

In various embodiments, this disclosure describes systems and methods that describe the integration of one or more components (for example, connectors) having terminations (for example, solder terminations) into a package (for example, an embedded die package). Further, one or more RDLs can be applied to the components. Some example die packages that can be used in connection with the disclosure include embedded wafer level ball grid array (eWLB) and/or embedded die in laminate packages. In various embodiments, it is noted that the disclosed systems and methods can permit or otherwise facilitate a wider selection and easy availability of the components to be electrically and/or mechanically coupled to one or more packages. In various embodiments, it is also noted that the disclosed systems and methods can reduce process complexity, for example, process complexity in the fabrication and/or integration of more components having terminations (for example, solder terminations) into a package (for example, an embedded die package). In various embodiments, it is further noted that the disclosed systems and methods can improve reliability and/or the yield in the fabrication and/or integration of more components having terminations (for example, solder terminations) into a package (for example, an embedded die package).

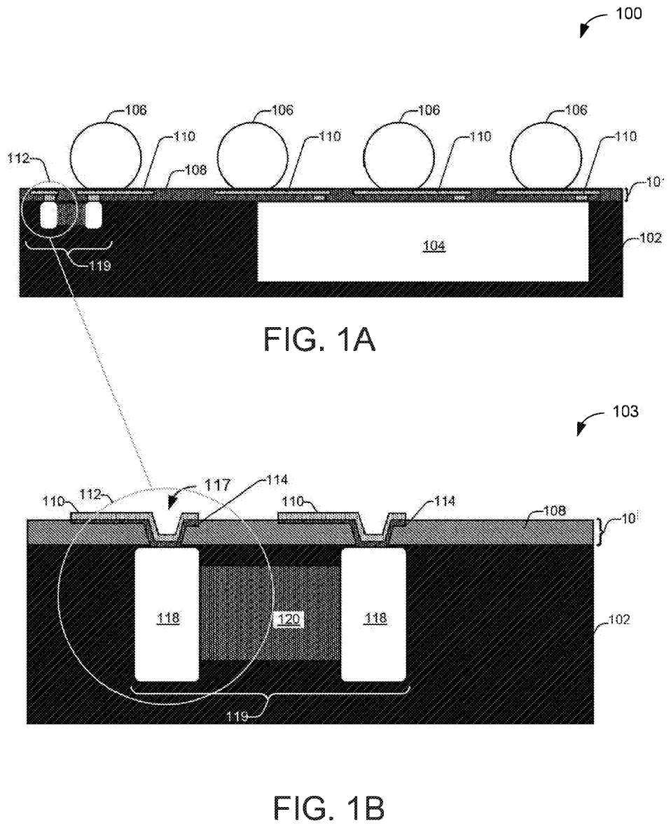

FIG. 1A illustrates a diagram of an embedded wafer level ball grid array (also referred to as EWLB or eWLB herein) package 100 in accordance with one or more embodiments of this disclosure. The EWLB package 100 can further include a mold frame 102. The mold frame 102 can further include one or more chips and/or a dies 104 that can be embedded within the mold frame 102. The EWLB package 100 can further include a redistribution dielectric layer (RDL) 101. The RDL 101 can further include one or more metal layers and/or pads 110 and one or more build-up or dielectric layers 108. Further the EWLB package 100 can include interconnects 106, for example, including solder balls. In some embodiments, the interconnects 106 can include a ball grid array (BGA). The dielectric layers 108 can include, but need not be limited to, any suitable material, for example, an oxide. Further, the dielectric layer 108 can include a photostructurable dielectric material, for example, polyimide or polybenzoxazole (PBO). Other materials also can be contemplated. However, in some implementations, one or more via openings (not shown) may be more difficult to fabricate and may need, for example, the use of a masked etching process or a laser. The dielectric layers 108 can comprise any suitable dielectric material including, for example, silicon dioxide or any other known oxide. The dielectric layers 108 can further comprise an organic material or polymer material, a prepreg material, a ceramic, a glass, silicone, or any other kind of suitable material. Further, in various aspects, the dielectric layers 108 can comprise a polymer material, ceramic material, plastics, composite materials, liquid crystal polymers (LCP), epoxy laminates of fiberglass sheets, prepreg, FR-4 materials, FR-5 materials, combinations thereof, or the like. The metal layers (optionally having a plurality of pads) 110 can include copper, silver, or any other suitable metal. The number of layers in the dielectric layers 108 and/or the metal layers and/or pads 110 of the RDL 101 can be any suitable number and may, in various embodiments, depend on the number of connections to be made by the RDL 101 and one or more external connections, for example, to power supplies, off-board integrated circuits and/or memory, and the like.

In one embodiment, there can be a component 119 (shown in an enlarged view in FIG. 1B, which can alternatively be referred to as a solid assembly herein) which can electrically connect to the RDL 101 at interface connection regions 112, for example, one or more interface connection regions 112 with a metal layers and/or pads 110 of the RDL 101. This can be, for example, in a fan out region of the EWLB package 100. The component 119 can be an embedded surface mount device (SMD) or a part of or electrically and/or mechanically coupled to an embedded surface mount device (SMD). The component 119 alternatively can be a part of or electrically and/or mechanically coupled to any other suitable device.

FIG. 1B illustrates another example view of the example interface connection region 112 of FIG. 1A, in accordance with one or more embodiments of this disclosure. For example, the mold frame 102 is shown in addition to portions of the dielectric layer 108 and at least a portion of the metal layers and/or pads 110. In one embodiment, the metal layers and/or pads 110 can include a metal trace. The metal layers and/or pads 110 can further include a copper trace material and a seed and/or adhesion layer 114. In one embodiment, the seed and/or adhesion layer 114 can include titanium (Ti) and/or tungsten (Tu) material and/or any combination and/or oxides, intermetallics, and/or alloys thereof that are in substantial contact with one another. Further, the metal layers and/or pads 110 can be connected to the dielectric layer 108 of the RDL 101 of FIG. 1A at one or more interface/connection region(s) 112. As shown in FIG. 1B, the metal layers and/or pads 110, the seed and/or adhesion layer 114, and/or a portion of the component 119 can form an electrical connection at one or more interface connection region(s) 112. For example the component can be an embedded surface mount device (SMD). The electrical connection can be formed at the interface connection region 112 between a solder termination interface of a solder termination member 118 of the component 119. The component 119 can further include a coupling element 120, which can serve to connect one or more solder termination members 118 of the component 119. In one embodiment, the coupling element 120 can include a ceramic material. In one embodiment, the coupling element 120 can partially house one or more electronic components, e.g., application specific integrated circuits (ASICS), resistors, capacitors, and the like. While the coupling elements 120 is shown in FIG. 1A and FIG. 1B as connecting the two termination members 118 on respective side surfaces of the termination members 118, other embodiments can be contemplated (not shown) where a coupling element (similar, but not necessarily identical to, the coupling element 120 of FIG. 1A and FIG. 1B) can connect two termination members (similar, but not necessarily identical to, the termination members 118 of FIG. 1A and FIG. 1B at other surfaces of the termination members 118, for example, at respective bottom ends of the termination members. The metal layers and/or pads 110 can, in various embodiments, be plated into the dielectric layer 108. In another embodiment, a via 117 can be opened in the dielectric layer 108 prior to the plating of the metal layers and/or pads 110 in the via 117. Further, in one or more embodiments, the seed and/or adhesion layer 114 can be formed in the patterned dielectric layer 108 prior to the plating of the metal layers and/or pads 110. Some of the processes for the fabrication of the RDL 101 can include, but not be limited to, coating the dielectric layer 108, opening one or more vias 117 in the dielectric layer 108, sputtering the seed and/or adhesion layer 114, coating and patterning a photoresist layer (not shown) deposited on the seed and/or adhesion layer 114, electroplating one or more metal layers and/or pads 110 on the RDL 101, removing the photoresist layer, and/or etching the seed and/or adhesion layer 114. The seed and/or adhesion layer 114 can be formed using any suitable method including, for example, sputtering, paste printing, atomic layer deposition (ALD), chemical catalytic deposition from solution, or a variety of different physical vapor deposition (PVD) techniques. In one embodiment, the seed and/or adhesion layer 114 can serve as a plating base for plating the RDL 101.

In various embodiments, the connection between the metal layers and/or pads 110 can include a region including, but not limited to, metal trace material (for example, Cu), seed and/or adhesion layer material (e.g. titanium Ti/tungsten Tu), solder material (for example, tin Sb), and/or any combination of and/or oxides, intermetallics, and/or alloys thereof that are in substantial contact with one another. The interface between the seed and/or adhesion layer 114 and the solder termination member 118 of the component 119 can become unstable. For example, the interface between the seed and/or adhesion layer 114 and the solder termination member 118 of the component 119 can become unstable during rapid thermal annealing and/or other processing steps.

In various embodiments, FIGS. 1A-1B illustrate at least one problem that can occur with integrating components having terminations (for example, solder terminations) into a package, for example, the EWLB 100. As described above, during the fabrication/processing of the EWLB using standard processing flows, one or more vias (for example, vias 117) may be formed in the dielectrics 108 of the RDLs 101. There RDL 101 can further include a sputtered seed and/or adhesion layer 114 and metal layers and/or pads 110 (for example, electroplated Cu traces). The interface of the portion of component (for example, solder, Sn, and/or Pb)—seed and/or adhesion layer (for example, Ti/Tu)—metal layer/trace (for example, Cu) may not be stable when stressed thermally. The thermal stressing can be caused, for example, by multiple reflows or by reliability tests involving high temperatures over extended time. When embedding into laminate or printed circuit board (PCB) the problem can be similar: in that case, vias (for example, vias 117) may be formed by laser drilling, and the seed and/or adhesion layer 114 may be deposited chemically. Nevertheless, a similar interface can be present as in EWLB discussed above, e.g., interconnect (for example, solder)—seed and/or adhesion layer—metal layer/trace, and thus, comparable failure modes may be expected.

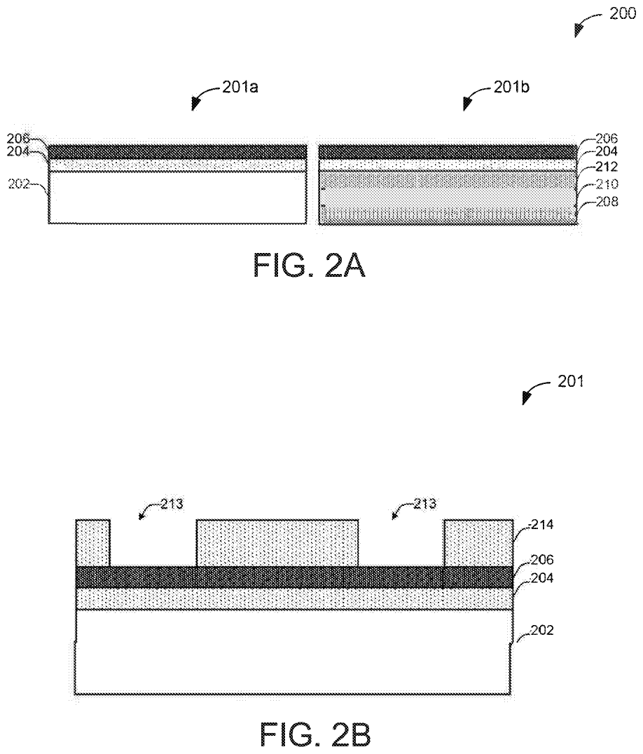

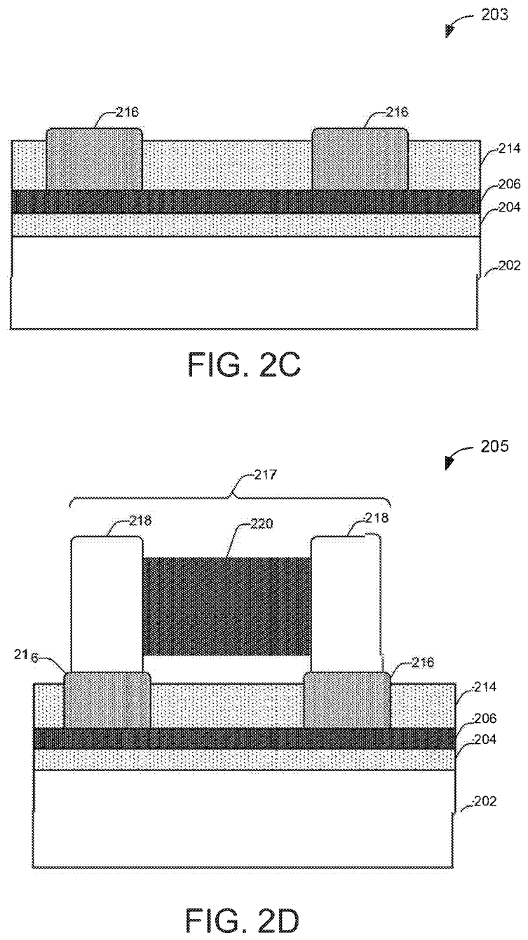

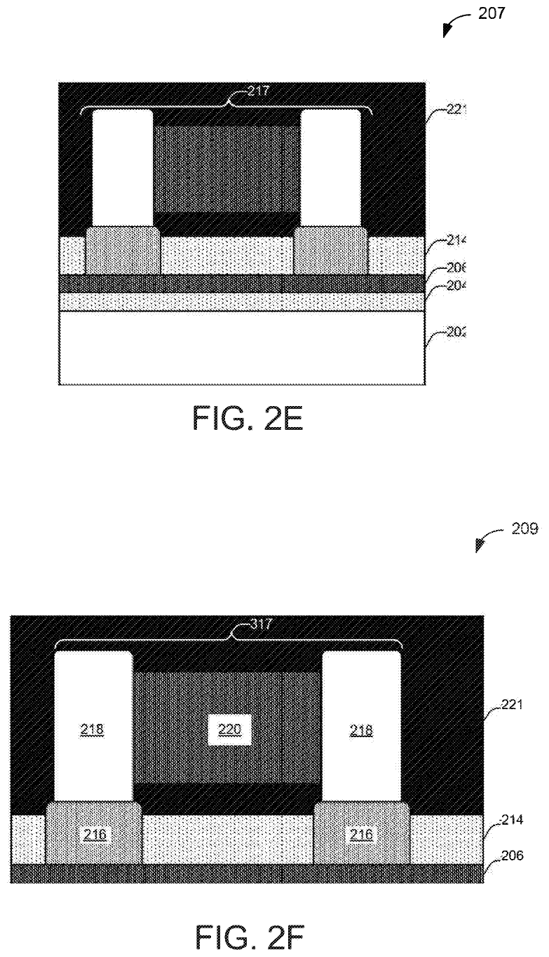

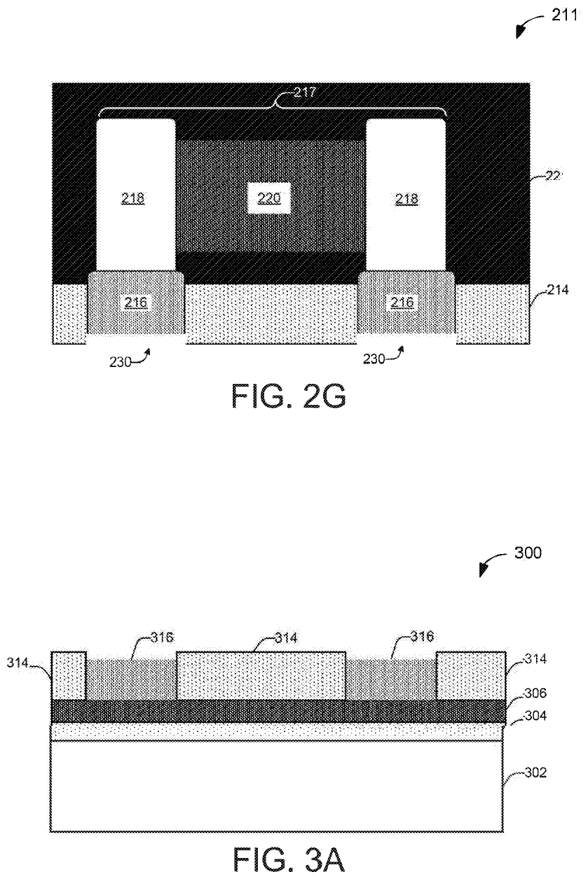

FIGS. 2A-2G illustrate diagrams representing a processing sequence for the formation of one or more metal pads (for example, Cu pads) on at least one surface associated with a solder termination member of a component, for example, a component associated with an SMD, in accordance with embodiments of the disclosure.

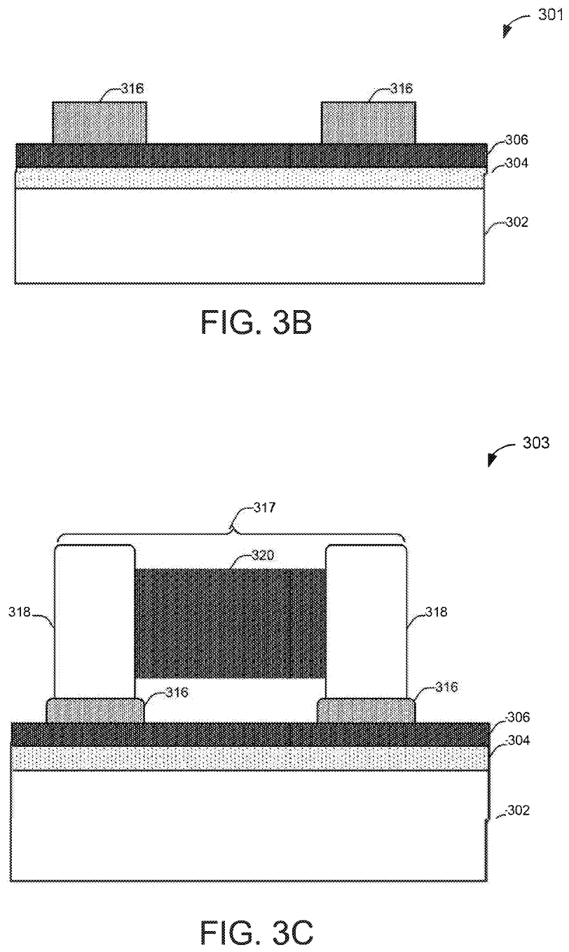

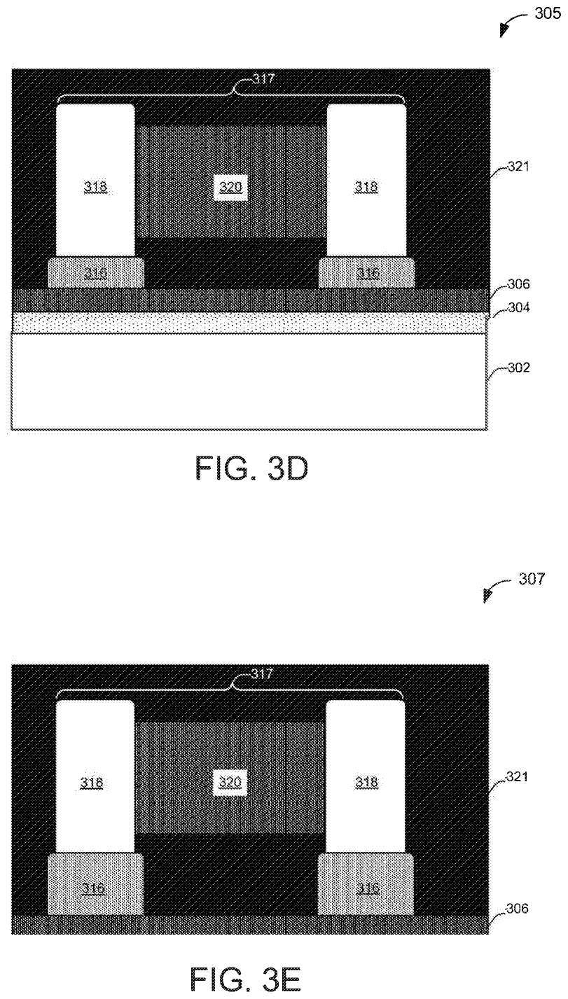

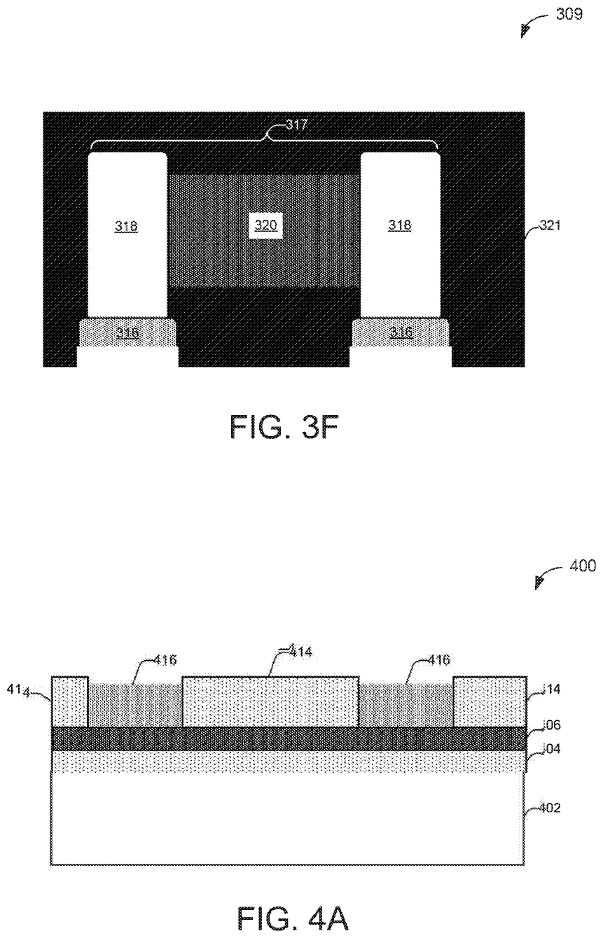

FIG. 2A shows an example diagram 200 of the example processing sequence for the formation of one or more metal pads (for example, Cu pads) on at least one surface associated with a solder termination member of a component, for example, a component associated with an SMD, in accordance with the one or more embodiments of the disclosure. As shown in FIG. 2A, a first structure 201a including a carrier layer 202, a release layer 204, and a metal layer 206 (for example, a Cu foil) can be provided. In various embodiments, the metal layer 206 (and other metal layers/metal foil layers 306, 406, and/or 506 used in connection with FIGS. 3A-5D), can additionally or alternatively be referred to as seed and/or adhesion layers herein. Further, as shown in another view of the first structure 201b, the carrier layer 202 can include a printed circuit board (PCB) core 208, a prepreg layer 210, and a metal (for example, Cu) carrier foil layer 212.

In one or more embodiments, the metal carrier foil layer 212 (for example, including a copper carrier foil), the release layer 204, and the metal foil layer 206 may be available as a commercial product. Further, this three-layer foil can be laminated onto the PCB core 208, for example, using the prepreg layer 210.

In various embodiments, the metal foil layer 206 (and other metal layers/metal foil layers 306, 406, and/or 506 used in connection with FIGS. 3A-5D), can additionally or alternatively be referred to as seed and/or adhesion layers herein, and can comprise aluminum, silver, copper, and the like, and/or an alloy of aluminum, silver, copper, and the like. The metal layer can be deposited via electroplating, sputtering, atomic layer deposition (ALD), or a variety of different physical vapor deposition (PVD) techniques. The metal layer 206 (and other metal layers/metal foil layers) may be laminated on top of any other layer by any suitable process, including, for example, cold roll or hot roll. Additionally the metal foil layer 206 can be deposited via any of the above mentioned techniques (or others that are not explicitly named herein) and then picked and placed on any other layer, laminated thereon, or positioned atop any other layer via any other suitable technique. In one embodiment, the deposition of the metal layer on a carrier layer can be performed in a way that permits or otherwise facilitates debonding and that ensures adhesion and debondability after subsequent processing steps. In one embodiment, such a deposition can be performed using a release layer. For example, the mentioned 3-layer foil can permit or otherwise facilitate the debonding.

FIG. 2B shows another example diagram 201 of the example processing sequence for the formation of one or more metal pads (for example, Cu pads) on at least one surface associated with a solder termination member of a component, for example, a component associated with an SMD, in accordance with the example embodiments of this disclosure. Here the carrier layer 202, the release layer 204, and the metal foil layer 206 (for example, copper foil) is shown. Additionally, a plating resist layer 214 is shown. The plating resist layer 214 can comprise, for example, a photoresist. Further, the plating resist layer 214 can be a permanent layer in various embodiments for example polyimide or SU8. Moreover, the plating resist layer 214 can be patterned to produce one or more cavities and/or vias 213. In various examples, polyimide can be chosen for the plating resist layer 214, for example, due to its temperature resistance properties and/or its chemical stability properties.

FIG. 2C illustrates another example diagram 203 of the example processing sequence for the formation of one or more metal pads (for example, Cu pads) on at least one surface associated with a solder termination member of a component, for example, a component associated with an SMD, in accordance with one or more embodiments of the disclosure. FIG. 2C again shows the carrier layer 202, the release layer 204, and the metal foil (for example, a copper foil) layer 206. Further, FIG. 2C shows the plating resist layer 214 which has been patterned previously as shown in FIG. 2B. Moreover, FIG. 2C shows one or more pads 216. The one or more pads 216 can comprise metal pads. The metal pads 216 can be made from any suitable material including, but not limited to, copper, tin, silver, gold and/or combination, alloy, and/or intermetallic thereof, and the like. Further, the pads 216 can be electroplated and/or formed using any other suitable process including, but not limited to, sputtering, paste printing, squeegee, atomic layer deposition (ALD), or a variety of different physical vapor deposition (PVD) techniques. The one or more pads 216 may be laminated on top of any other layer by any suitable process including, for example, cold roll or hot roll. In one embodiment, the one or more pads 216 may protrude slightly above the level of the plating resist layer 214, which may lead to the pads taking on a mushroom-shaped top, not shown). In one embodiment, if the one or more pads 216 are electroplated into the plating resist layer 214, the protrusions may not exist as the pads can be laterally confined. Other methods may lead to metal deposition also onto the plating resist layer 214 so an additional patterning step or method may need to be applied to remove this residual deposition if desired.

FIG. 2D illustrates another example diagram 205 of the example processing sequence for the formation of one or more metal pads (for example, Cu pads) on at least one surface associated with a solder termination member of a component, for example, a component associated with an SMD, in accordance with one or more embodiments of the disclosure. FIG. 2D again shows the carrier layer 202, the release layer 204, the metal foil layer 206 (for example, a copper foil layer 206), the plating resist layer 214, and the pads 216. Further a component 217 is shown. The component 217 can include a solder termination member 218 of the component 119, and the component 217 can further include a coupling element 220. In various embodiments, the component 217 can be soldered to the pads 216 using various SMD assembly processes. For example, the component 217 can be soldered to the pads 216 by printing solder paste on the pads 216 and/or flux dipping of the component 217. While the coupling elements 220 shown in FIG. 2D and subsequent figures are shown as connecting the two termination members 218 on respective side surfaces of the termination members 218, other embodiments can be contemplated (not shown) where a coupling element (similar, but not necessarily identical to, the coupling element 220 of FIG. 2D) can connect two termination members (similar, but not necessarily identical to, the termination members 218 of FIG. 2D at other surfaces of the termination members 218, for example, at respective top or bottom ends of the termination members.

FIG. 2E illustrates another example diagram 207 of the example processing sequence for the formation of one or more metal pads (for example, Cu pads) on at least one surface associated with a solder termination member of a component, for example, a component associated with an SMD, in accordance with one or more embodiments of the disclosure. FIG. 2E again shows the carrier layer 202, the release layer 204, the metal foil layer 206 (for example, a copper foil layer 206), the plating resist layer 214, the pads 216, and the component 217 including the solder termination member 218. Further shown is a molding layer 221 which can be formed on top of the component 217 and the plating resist layer 214. The molding layer 221 can encapsulate the component 217. The formation of the molding layer 221 on the component 217 can result in a panel and/or a reconstituted wafer bonded to the carrier layer 202. The resulting structure can hereinafter be referred to as a panel and/or a reconstituted wafer as shown in FIG. 2F (diagram 209), described below. In other aspects, the molding layer 221 can be made partially or fully from a molding compound which may be any suitable molding material. The molding layer 221, in example embodiments, may be any suitable thickness.

FIG. 2F shows another example diagram 209 of the example processing sequence for the formation of one or more metal pads (for example, Cu pads) on at least one surface associated with a solder termination member of a component, for example, a component associated with an SMD, in accordance with one or more example embodiments of the disclosure. As shown in FIG. 2F, the metal foil layer 206 with the components 217 and the molding layer 221 has been removed from a carrier layer (for example, the carrier layer 202 shown in FIG. 2E). For example, the panel and/or the reconstituted wafer can be debonded from the carrier layer 202, for example, using the release layer 204.

FIG. 2G illustrates another example diagram 211 of the example processing sequence for the formation of one or more metal pads (for example, Cu pads) on at least one surface associated with a solder termination member of a component, for example, a component associated with an SMD, in accordance with one or more embodiments of the disclosure. As can be seen in FIG. 2G, the metal foil layer 206 (for example, the copper foil layer 206) has been etched from the panel and/or reconstituted wafer shown in diagram 209 of FIG. 2F. For example, the metal foil layer 206 can be etched in order to expose the pads 216. In various embodiments, the etching can include a slight over-etch of the metal foil layer 206 to slightly recess the pads 216.

In various embodiments, the systems and methods disclosed in relation to FIGS. 2A-2G illustrate a single component processed on the carrier layer, which can be understood to be for simplification only. Thus, one or more (for example, 10s, 100s, 1000s, etc.) of components can be formed using the one or more carrier layers and can be processed in parallel or substantially in parallel, depending on manufacturing conditions.

The encapsulated component as depicted by the diagram 211 can then be singulated, for example, by mechanical dicing. The singulation of the encapsulated component can result in an encapsulated component with one or more metal terminations, for example, one or more copper terminations. These copper terminations can be suitable for EWLB packaging with RDL vias and/or for integration into laminates with PCB technology microvias.

In various embodiments, FIGS. 2A-2G present diagrams illustrating the example processing sequence for the formation of one or more metal pads (for example, Cu pads) on at least one surface associated with a solder termination member of a component, for example, a component associated with a 2-termination SMD, such as a resistor and/or a ceramic capacitor. In other embodiments, the systems and methods disclosed in relation to FIGS. 2A-2G can also be applicable to SMDs with higher input/output (I/O) count.

In various embodiments, the systems and methods disclosed in relation to FIGS. 2A-2G are understood to not be limited to a specific carrier layer system (for example, the disclosed carrier layer 202 of FIG. 2A that includes the printed circuit board (PCB) core 208, the prepreg layer 210, and the metal (for example, Cu) carrier foil 212). Other carrier layers (similar, but not necessarily identical to, the carrier layer 202 of FIG. 2A) can be used if the carrier layers are compatible with the described pad generation process described in connection with FIGS. 2A-2G and are compatible with soldering methods. In one embodiment, compatibility can mean that the carrier layer may need to physically withstand the pad generation process and/or the soldering methods/processes without losing adhesion and/or debonding capability. For example, the metal carrier foil 212 layer may be attached to a rigid carrier layer (similar, but not identical to, the carrier layer 202 of FIG. 2A) using an adhesive material, where the adhesive material does not reduce its adhesive properties below and/or approximate to the soldering temperature used during the soldering process.

FIGS. 3A-3F show example diagrams of another example processing sequence for the formation of one or more metal pads (for example, Cu pads) on at least one surface associated with a solder termination member of a component, for example, a component associated with an SMD, in accordance with one or more embodiments of the disclosure. As shown in FIGS. 3A-3F, the plating resist layer is not a permanent layer and can be removed after plating as shown, for example, in FIGS. 3A and 3B. The remaining flow of the processing sequence can be similar to but not identical to the processing sequence as shown in FIGS. 2D-2G.

The resulting component of the processing sequence shown in FIGS. 3A-3F can be different than the resulting component of the processing sequence of FIGS. 2A-2G. for example, because the bottom surface of the component cannot be covered by a permanent resist.

FIG. 3A shows an example diagram 300 of the example processing sequence for the formation of one or more metal pads (for example, Cu pads) on at least one surface associated with a solder termination member of a component, for example, a component associated with an SMD, in accordance with one or more example embodiments of the disclosure. FIG. 3A can be considered similar to FIG. 2C but not identical to FIG. 2C. For example, the metal pads 216 of FIG. 2C can extend above the plating resist layer 214 of FIG. 2C. However, similar metal pads 316 of FIG. 3A may not extend above the plating resist layer 314 of the FIG. 3A. Further, FIG. 3A illustrates a carrier layer 302, a release layer 304, a metal foil layer 306 (for example, a copper foil layer 306) a plating resist layer 314, and pads 316. The metal pads 316 can include copper pads or can be made from any suitable material including, but not limited to, aluminum, silver, copper and the like, and/or an alloy of aluminum, silver, copper, combinations thereof, or the like.

FIG. 3B illustrates an example diagram 301 of the example processing sequence for the formation of one or more metal pads (for example, Cu pads) on at least one surface associated with a solder termination member of a component, for example, a component associated with an SMD, in one or more example embodiments of the disclosure. As shown in FIG. 3B, the plating resist layer 314 of FIG. 3A has been removed. For example, the removal of the plating resist layer 314 can be performed by any suitable method including, but not limited to, plasma ashing, etching, solvent based resist stripping, or any other suitable semiconductor manufacturing step(s). FIG. 3B shows the carrier layer 302, the release layer 304, the metal foil layer 306 and the remaining pads 316.

FIG. 3C illustrates an example diagram 303 of the example processing sequence for the formation of one or more metal pads (for example, Cu pads) on at least one surface associated with a solder termination member of a component, for example, a component associated with an SMD, in accordance with one or more embodiments of the disclosure. Again, as can be seen in FIG. 3C, a carrier layer 302, a release layer 304, a metal foil layer 306 (for example, a copper foil layer), and pads 316 are shown. Additionally, a component 317 is shown connected to the pads 316. The component 317 can include a solder termination member 318, and a coupling element 320. The component 317 can, in various example embodiments, be soldered to the pads 316 using a standard SMD assembly process. In various embodiments, soldering of the component to the pads may involve applying a solder paste or printing a solder paste on the pads 316 and/or flux dipping the component 317 prior to electrically connecting the component 317 with the pads 316. While the coupling element 320 shown in FIG. 3C and subsequent figures is shown as connecting the two termination members 318 on respective side surfaces of the termination members 218, other embodiments can be contemplated (not shown) where a coupling element (similar, but not necessarily identical to, the coupling element 320 of FIG. 3C) can connect two termination members (similar, but not necessarily identical to, the termination members 318 of FIG. 3C at other surfaces of the termination members 318, for example, at respective bottom ends of the termination members.

FIG. 3D illustrates an example diagram 305 of the example processing sequence for the formation of one or more metal pads (for example, Cu pads) on at least one surface associated with a solder termination member of a component, for example, a component associated with an SMD, in accordance with one or more embodiments of the disclosure. FIG. 3D again shows the carrier layer 302, the release layer 304, the metal foil layer 306 (for example, copper foil layer), the pads 316, the component 317 including the solder termination member 318 and the coupling element 320. Furthermore, a molding layer 321 is shown. The molding layer 321 can be used to encapsulate the component 317 in accordance with one or more embodiments.

FIG. 3E illustrates an example diagram 307 of the example processing sequence for the formation of one or more metal pads (for example, Cu pads) on at least one surface associated with a solder termination member of a component, for example, a component associated with an SMD, in accordance with one or more embodiments of the disclosure. FIG. 3E illustrates a structure that represents the diagram 305 of FIG. 3D with the carrier layer 302 removed, for example, using the release layer 304. The removal of the carrier layer 302 as shown in FIG. 3E can be performed by any suitable mechanism and/or method including, but not limited to, debonding from the metal foil layer 306. In one embodiment, debonding can be performed using a peeling off step and/or a shearing off step. Further, to permit or otherwise facilitate debonding, the adhesive strength of the release layer may be reduced, for example, by increasing the temperature, by applying UV-radiation (in the case of a transparent carrier layer, for example, a transparent carrier layer 302) or by the use of one or more solvents.

FIG. 3F illustrates an example diagram 309 of the example processing sequence for the formation of one or more metal pads (for example, Cu pads) on at least one surface associated with a solder termination member of a component, for example, a component associated with an SMD, in accordance with one or more embodiments of the disclosure. As shown in FIG. 3F, the metal foil layer 306 (for example, the copper foil layer) of FIG. 3E has been removed (for example, etched) from the structure shown in FIG. 3F (diagram 309). The metal foil layer 306 of FIG. 3E can be etched in various embodiments, for example, in order to expose the pads 316 (for example, copper contact pads). In various embodiments, a slight over-etching of the metal foil layer 306 can ensure the removal of the metal foil layer 306 and can lead to slightly recessed pads 316 (for example, with respect to the molding layer 321). The component 317 that has been encapsulated by the molding layer 321 can then be singulated, for example, by a mechanical dicing method. This can result in an encapsulated component 317 with metal terminations, for example, with copper terminations. These metal terminations (for example, copper terminations) can be suitable for EWLB packaging with RDL vias and/or for integration into one or more laminates with printed circuit board (PCB) technology-based vias and/or microvias.

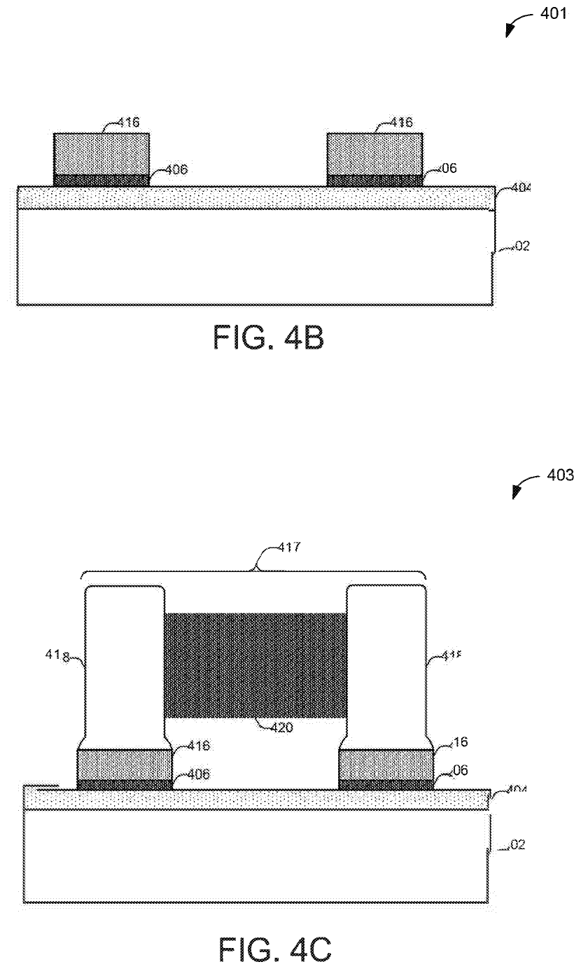

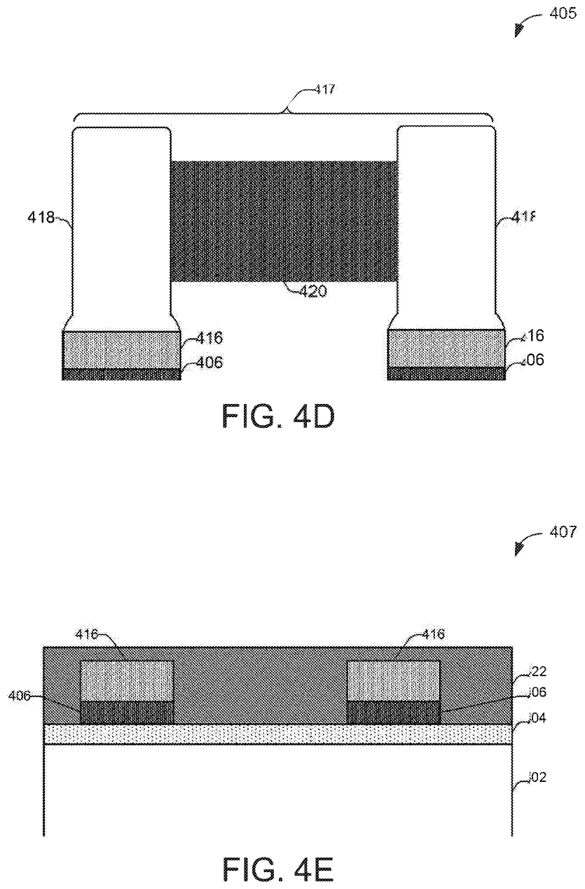

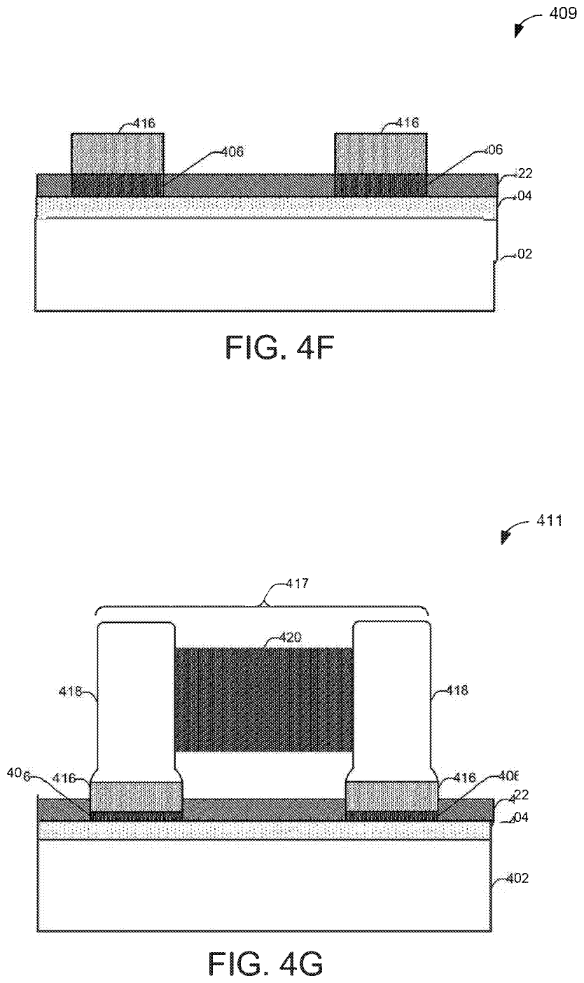

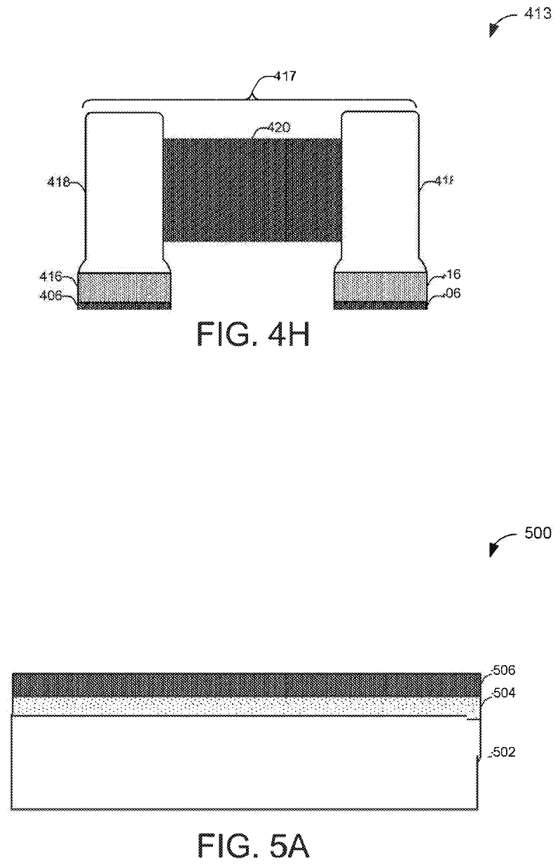

FIGS. 4A-4H illustrate another processing sequence for the formation of one or more metal pads (for example, Cu pads) on at least one surface associated with a solder termination member of a component, for example, a component associated with an SMD, in accordance with one or more embodiments of the disclosure.

In particular, FIGS. 4A-4D illustrate an alternative processing sequence wherein the plating resist layer 414 and/or the metal foil layer 406 can be removed after plating the pads 416 (for example, as shown in FIG. 4B). Further the component 417 can be soldered onto the pads 416 as shown in FIG. 4C and be debonded from the carrier layer 402, as shown in FIG. 4D. This can allow for the elimination of the molding and/or the singulation steps. However, it can expose the release layer 404 to etchants, for example, during the etching of the metal foil layer 406 and/or to solder materials and/or processes, for example, during the soldering process used in the processing sequence. In various embodiments, additional care needs to be taken in order to avoid the negative impact on adhesion and/or debonding capability associated with any of the constituent elements of the structures depicted the FIGS. 4A-4D during any of the aforementioned processes.

FIG. 4A illustrates an example diagram 400 of the example processing sequence for the formation of one or more metal pads (for example, Cu pads) on at least one surface associated with a solder termination member of a component, for example, a component associated with an SMD, in accordance with one or more embodiments of the disclosure. As shown in FIG. 4A a carrier layer 402 can be provided in addition to a release layer 404, a metal foil layer 406 (for example, a copper foil layer), a plating resist layer 414, and pads 416 (for example, metal pads 416). The pads 416 can additionally include a copper metal pads. The plating resist layer 414 can be patterned using any suitable method prior to the plating of the metal pads 416, for example, similar but necessarily identical as described in previous figures (see for example FIGS. 2A-3F and the relevant description).

FIG. 4B illustrates an example diagram 401 of the example processing sequence for the formation of one or more metal pads (for example, Cu pads) on at least one surface associated with a solder termination member of a component, for example, a component associated with an SMD, in accordance with one or more embodiments of the disclosure. FIG. 4B again illustrates the carrier layer 402, the release layer 404 and further shows a patterned metal foil layer 406 and pads 416. As mentioned, the plating resist layer 414 and the metal foil layer 406 can be etched and removed, at least partially removed, after plating the pads 416, which is why the metal foil layer 406 is not shown in FIG. 4B. The etching of the plating resist layer 414 and/or the metal foil layer 406 can be performed using any suitable method.

FIG. 4C illustrates an example diagram 403 of the example processing sequence for the formation of one or more metal pads (for example, Cu pads) on at least one surface associated with a solder termination member of a component, for example, a component associated with an SMD, in accordance with one or more embodiments of the disclosure. FIG. 4C again shows the carrier layer 402, the release layer 404, the patterned metal foil layer 406, the pads 416 and additionally, a component 417. The component 417 can further include a soldering termination member 418 and a coupling element 420. The component 417 can mechanically couple (for example, be soldered) to the pads 416 using standard SMD assembly processes. For example, in various embodiments, this can involve printing solder paste on the pads 416 and/or flux dipping of the component 417. While the coupling element 420 shown in FIG. 4C and subsequent figures are shown as connecting the two termination members 418 on respective side surfaces of the termination members 218, other embodiments can be contemplated (not shown) where a coupling element (similar, but not necessarily identical to, the coupling element 420 of FIG. 4C) can connect two termination members (similar, but not necessarily identical to, the termination members 418 of FIG. 4C at other surfaces of the termination members 418, for example, at respective bottom ends of the termination members.

FIG. 4D illustrates an example diagram 405 of the example processing sequence for the formation of one or more metal pads (for example, Cu pads) on at least one surface associated with a solder termination member of a component, for example, a component associated with an SMD, in accordance with one or more embodiments of the disclosure. FIG. 4D illustrates a remaining structure resulting from the removal of the carrier layer 402 of FIG. 4C. Therefore what remains, as depicted in FIG. 4D, are the patterned metal foil layer 406, the pads 416, and the component 417 including the soldering termination member 418 and the coupling element 420. The removal of the carrier layer 402 can be performed using any suitable method including, but not limited to, debonding the carrier layer 402 and the release layer 404 from the patterned metal foil layer 406.

FIGS. 4E-4H illustrate a variation of the processing sequence of FIGS. 4A-4D in accordance with one or more embodiments of the disclosure. As shown in FIGS. 4E-4H, after the removal of the metal foil layer 406, a planarizing passivation layer 422 can be applied to the structures depicted in one or more of FIGS. 4E-4H. In one embodiment, the pads 416 may then be exposed by a uniform back etch. In one embodiment, the planarizing passivation layer 422 can be used to shield and/or protect the underlying layers during the soldering processes in connection with the formation of one or more metal pads (for example, Cu pads) on at least one surface associated with a solder termination member of a component.

FIG. 4E illustrates an example diagram 407 of the example processing sequence for the formation of one or more metal pads (for example, Cu pads) on at least one surface associated with a solder termination member of a component, for example, a component associated with an SMD, in accordance with one or more embodiments of the disclosure. FIG. 4E again shows a carrier layer 402, a release layer 404, a patterned metal foil layer 406, one or more pads 416, and additionally shows a planarizing passivation layer 422. The planarizing passivation layer 422 can be used to protect the underlying release layer 404 in various etching steps as further discussed in connection with FIG. 4F. In various embodiments, the planarizing passivation layer 422 can be applied and/or formed using any suitable method including, but not limited to, lamination, spin coating, spray coating, sputtering, paste printing, squeegee, atomic layer deposition (ALD), or a variety of different physical vapor deposition (PVD) techniques.

FIG. 4F illustrates an example diagram 409 of the example processing sequence for the formation of one or more metal pads (for example, Cu pads) on at least one surface associated with a solder termination member of a component, for example, a component associated with an SMD, in accordance with one or more embodiments of the disclosure. FIG. 4F again shows the carrier layer 402, the release layer 404, the patterned metal foil layer 406, the pads 416, and additionally shows a back-etched planarizing passivation layer 422. The etching of the planarizing passivation layer 422 can be performed until the pads 416 are exposed. The planarizing passivation layer 422 can protect the release layer 404 during the soldering steps shown below (for example, see FIG. 4G and related discussion).

FIG. 4G illustrates an example diagram 411 of the example processing sequence for the formation of one or more metal pads (for example, Cu pads) on at least one surface associated with a solder termination member of a component, for example, a component associated with an SMD, in accordance with one or more embodiments of the disclosure. FIG. 4G again shows the carrier layer 402, the release layer 404, the patterned metal foil layer 406, the pads 416, and the etched planarizing passivation layer 422. Additionally shown is the component 417 which can further include a solder termination member 418 and a coupling element 420. The component 417 can be mechanically coupled and/or applied to the pads using any suitable method. For example, the component 417 can be soldered to the pads 416 using a standard SMD assembly process. In various embodiments. this can involve printing and/or applying a solder paste material on the pads 416 and/or flux dipping the component 417.

FIG. 4H illustrates an example diagram 413 of the example processing sequence for the formation of one or more metal pads (for example, Cu pads) on at least one surface associated with a solder termination member of a component, for example, a component associated with an SMD, in accordance with one or more embodiments of the disclosure. FIG. 4H illustrates a remaining structure depicted in diagram 413 after the removal of the carrier layer 402 and the release layer 404 from the structure depicted in diagram 411 of FIG. 4G. FIG. 4H presents a diagram 413 of the remaining structure which can further include the patterned metal foil layer 406, the pads 416, and the component 417. The component 417 can further include a solder termination member 418 and a coupling element 420.

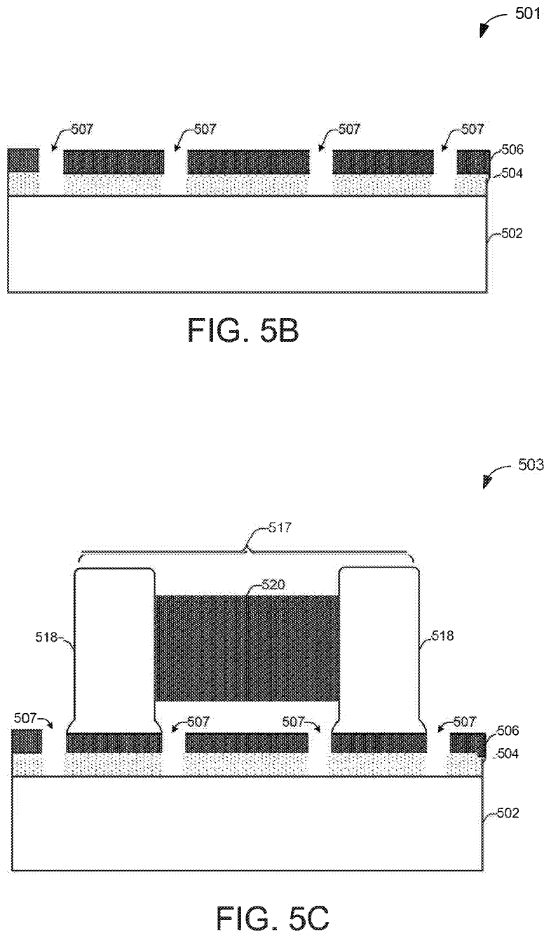

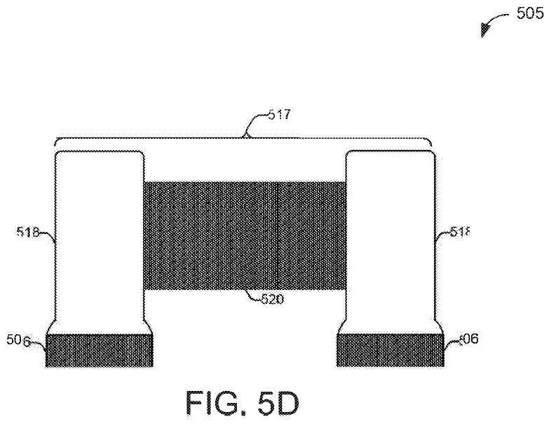

FIGS. 5A-5D illustrates an alternative processing sequence for the formation of one or more metal pads (for example, Cu pads) on at least one surface associated with a solder termination member of a component, for example, a component associated with an SMD, in accordance with one or more embodiments of the disclosure. For example, instead of forming pads (for example, the pads 216, 316 and/or 416 of FIGS. 2A-4H, respectively) using lithography and/or electroplating, the pads can be cut out of the metal foil (for example, the metal foil layer 506 shown in FIG. 5A), similar, but not necessarily identical to, the metal foil layers 206, 306, and/or 406 of FIGS. 2A-4H. The cutting out of pads from the metal foil layer 506 can be performed, for example, by laser and/or by a mechanical half cut dicing process, as shown in FIG. 5B, and/or by any other suitable process. The component (for example, the component 517 shown in FIG. 5C) can be soldered directly onto these pads, which may not be additionally reinforced by electroplating (see, for example, FIG. 5C and related description). In one embodiment, the component (for example, the component 517 shown in FIG. 5C) can be debonded from the carrier layer (for example, the carrier layer 502 as shown in FIGS. 5A, 5B, and 5C). In various example embodiments, this processing sequence shown in FIGS. 5A-5D can permit or otherwise facilitate the replacement of the pads which can be expensive to generate using, for example, electroplating with a cheaper cutting process. Another example advantage of the processing sequence shown in FIGS. 5A-5D can include that the release layer, for example, the release layer 504 for FIGS. 5A, 5B and/or 5C may not necessarily be exposed to any etchants during an etching process for the removal of the metal foil layer (for example, the metal foil layer 506 shown in FIGS. 5A, 5B and/or 5C). In one embodiment, in order to confine the solder materials on the pad and to prevent wetting on the surrounding Cu foil used in the soldering process in connection with the processing sequence shown in FIGS. 5A-5D, the cuts/vias and/or trenches 507 may be filled by a nonwetting material, e.g., a polymer material. In one embodiment, the filling of cuts/the vias and/or trenches 507 can be done using a screen printing process. In one embodiment, the residue of any materials (for example, solder, metal, dielectric, carrier layer material, etc.) on surfaces proximate to the vias and/or trenches 507 or of the structures after this and/or any other process described in connection with FIGS. 5A-5D can be cleaned by brushing. Alternatively or additionally, in other embodiments, a solder mask with openings slightly smaller than the pads may be used to produce similar, but not necessarily structures identical to, the structures depicted in connection with the processing sequence diagrams of FIGS. 5A-5D.

FIG. 5A illustrates an example diagram 500 of the example processing sequence for the formation of one or more metal pads (for example, Cu pads) on at least one surface associated with a solder termination member of a component, for example, a component associated with an SMD, in accordance with one or more embodiments of the disclosure. FIG. 5A illustrates a carrier layer 502, a release layer 504 and a metal foil layer 506 (for example, a copper foil layer). In one embodiment, this can be similar, but not necessarily identical to, the carrier layer 202, the release layer 204, and/or the metal foil layer 206 of FIG. 2A).

FIG. 5B illustrates an example diagram 501 of the example processing sequence for the formation of one or more metal pads (for example, Cu pads) on at least one surface associated with a solder termination member of a component, for example, a component associated with an SMD, in accordance with one or more embodiments of the disclosure. FIG. 5B again illustrates the carrier layer 502, the release layer 504 and the metal foil layer 506. Additionally, as can be seen in FIG. 5B, a series of vias and/or trenches 507 can be formed in the structure represented by the diagram 501. Again, the vias and/or trenches 507 can be made by any suitable mechanism and/or method, for example, a cutting process using a laser, by mechanical half cut dicing, and/or by any suitable process.

FIG. 5C illustrates an example diagram 503 of the example processing sequence for the formation of one or more metal pads (for example, Cu pads) on at least one surface associated with a solder termination member of a component, for example, a component associated with an SMD, in accordance with one or more embodiments of the disclosure. FIG. 5C again illustrates the carrier layer 502, the release layer 504, the metal foil layer 506, the one or more vias and/or trenches 507 in addition to a component 517 which can further comprise a first and second soldering termination member 518 and a coupling element 520. While the coupling elements 520 shown in FIG. 5C and subsequent figures are shown as connecting the two termination members 518 on respective side surfaces of the termination members 518, other embodiments can be contemplated (not shown) where a coupling element (similar, but not necessarily identical to, the coupling element 520 of FIG. 5C) can connect two termination members (similar, but not necessarily identical to, the termination members 518 of FIG. 5C at other surfaces of the termination members 518, for example, at respective bottom ends of the termination members.

In various embodiments, the component 517 can be soldered to the metal foil layer 506 using one or more standard SMD assembly processes. This can include printing and/or applying a solder paste on the metal foil layer 506 and/or flux dipping of the component 517. In various example embodiments, the solder can be confined on the metal foil layer 506 and can be prevented from wetting the surrounding metal foil layer 506 (for example, copper foil layers during the soldering). This can be performed in various embodiments by filling the vias and/or trenches 507 with a non-wetting material, for example, a polymer material and/or any other suitable material.

In various example embodiments, this process can be performed using a screen printing process. Further, in various embodiments, one or more residues of the material on the surface of the structure represented by diagram 503 can be cleaned by any suitable process including, but not limited to, a brushing method. Additionally or alternatively, a standard solder mask (not shown), with openings slightly smaller than the pads can be applied (not shown).

FIG. SD illustrates an example diagram 505 of the example processing sequence for the formation of one or more metal pads (for example, Cu pads) on at least one surface associated with a solder termination member of a component, for example, a component associated with an SMD, in accordance with one or more embodiments of the disclosure. In particular, FIG. 5D illustrates an example diagram 505 of the component 517 wherein the carrier layer 502 and the release layer 504 of FIG. 5C have been removed. The removal of the carrier layer 502 and the release layer 504 can be performed by any suitable mechanism including, but not limited to, plasma ashing, etching, or any other suitable semiconductor manufacturing step(s). Alternatively or additionally, the component 517 can be debonded (for example, peeled or sheared off) from the carrier layer 502 using one or more of increased temperature, the application of one or more solvents, and/or UV-exposure of the release layer 504.

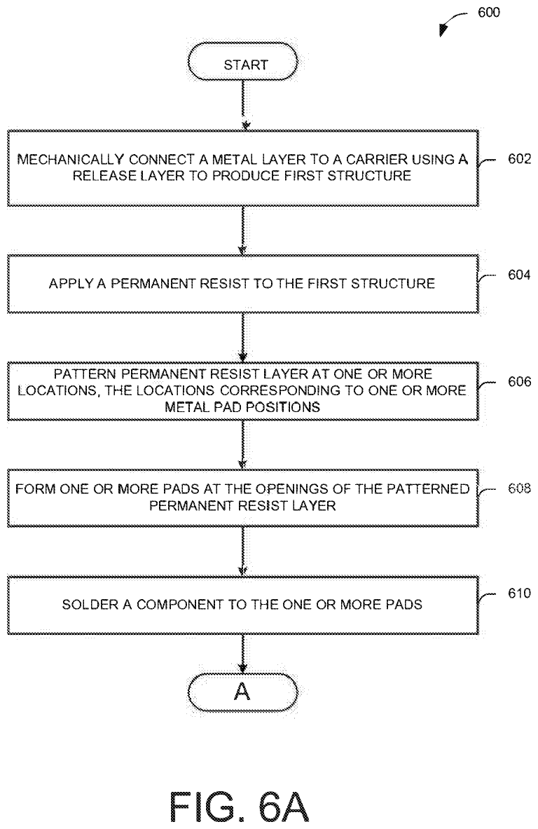

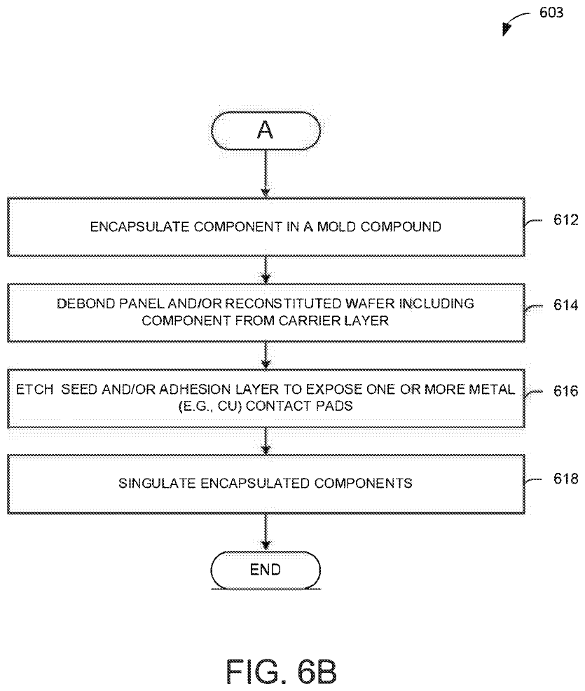

FIGS. 6A-6B depict diagrams illustrating an example method for fabricating the formation of one or more metal pads (for example, Cu pads) on at least one surface associated with a solder termination member of a component, for example, a component associated with an SMD, in accordance with example embodiments of the disclosure. This method 600 may be used to fabricate any of the components, as depicted in the preceding figures. It is noted that some processes may be performed in an order different from that depicted herein. It is also noted that some processes may have suitable substitutes that may be implemented without deviating from the embodiments of the disclosure.

With reference to FIG. 6A, in block 602, a metal (for example, Cu) layer (for example, foil) can be reversibly mechanically coupled to a carrier layer (for example, a carrier layer comprising a printed circuit board (PCB) core, a prepreg layer, and a metal, for example, a Cu layer), using a release layer, to produce a first structure. For further discussion, see FIG. 2A and the relevant description.

In block 604, a permanent resist layer can be applied to the first structure provided in block 602. The resist layer can comprise, for example, a photoresist. The resist layer can include, for example, polyimide or SU8. Moreover, the resist layer can be patterned to produce one or more cavities and/or vias.

In block 606, the permanent resist layer can be patterned at one or more locations to remove portions of the permanent resist layer, the locations corresponding to one or more metal pad positions. For further discussion, see FIG. 2B and the relevant description.

In block 608, one or more pads (for example, metal pads) can be formed (for example, plated) into the openings of the patterned permanent resist layer. The one or more pads may protrude slightly above the level of the patterned permanent resist layer. For further discussion, see FIG. 2C and the relevant description.

In block 610, a component can be soldered to the one or more pads using standard SMD assembly processes. For example, the process may involve solder paste printing the pads or flux dipping of the component. For further discussion, see FIG. 2D and the relevant description.

With reference to FIG. 6B, in block 612, the component can be over-molded and thereby encapsulated in a mold compound. This can result in a panel and/or a reconstituted wafer that can be bonded to the carrier layer. For further discussion, see FIG. 2E and the relevant description.

In block 614, the panel and/or reconstituted wafer including the component may be debonded from the carrier layer using any suitable technique. For further discussion, see FIG. 2F and the relevant description.

In block 616, the seed and/or adhesion layer can be etched exposing one or more metal (for example, Cu) contact pads. In one embodiment, slight over-etching may ensure the removal of the seed layer and can lead to slightly recessed pads.

In block 618, the encapsulated components can be singulated, for example, by mechanical dicing or any suitable technique. The result can yield encapsulated components with metal (for example, Cu) terminations. These metal terminations may be suitable for integration with one or more packages (for example, eWLB packages including RDL vias) or for integration into laminates, for example, laminates having microvias. For further discussion, see FIG. 2G and the relevant description.

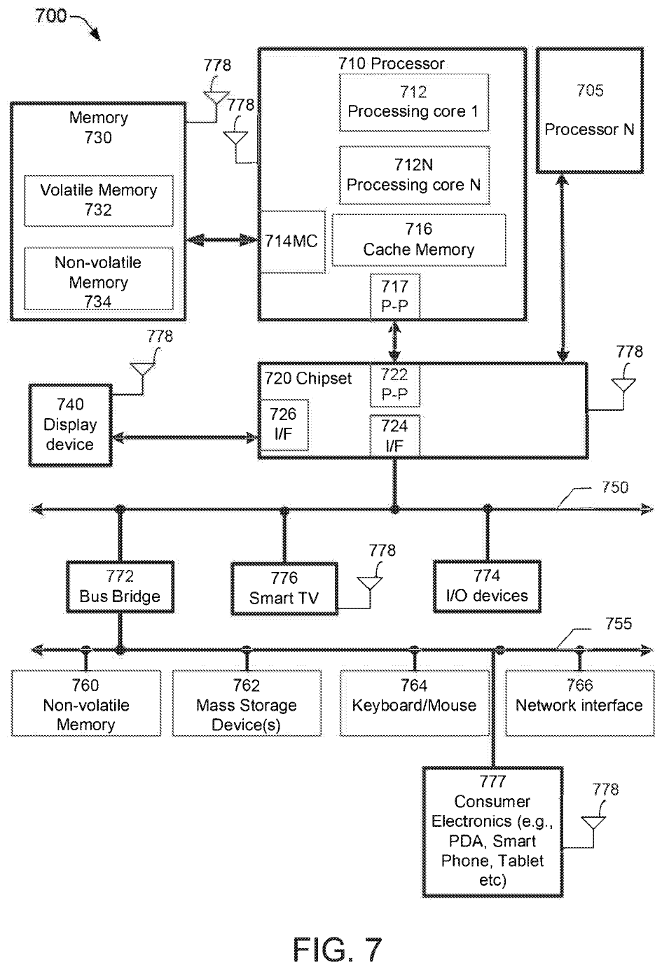

FIG. 7 depicts an example of a system 700 according to one or more embodiments of the disclosure. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 can include a system on a chip (SOC) system.

In one embodiment, system 700 includes multiple processors including processor 710 and processor N 705, where processor N 705 has logic similar or identical to the logic of processor 710. In one embodiment, processor 710 has one or more processing cores (represented here by processing core 1 712 and processing core N 712N, where 712N represents the Nth processor core inside processor 710, where N is a positive integer). More processing cores can be present (but not depicted in the diagram of FIG. 7). In some embodiments, processing core 712 includes, but is not limited to, pre-fetch logic to fetch instructions, decode logic to decode the instructions, execution logic to execute instructions, a combination thereof, or the like. In some embodiments, processor 710 has a cache memory 716 to cache instructions and/or data for system 700. Cache memory 716 may be organized into a hierarchical structure including one or more levels of cache memory.

In some embodiments, processor 710 includes a memory controller (MC) 714, which is configured to perform functions that enable the processor 710 to access and communicate with memory 730 that includes a volatile memory 732 and/or a non-volatile memory 734. In some embodiments, processor 710 can be coupled with memory 730 and chipset 720. Processor 710 may also be coupled to a wireless antenna 778 to communicate with any device configured to transmit and/or receive wireless signals. In one embodiment, the wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory device 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interface 717 and P-P interface 722. Chipset 720 enables processor 710 to connect to other elements in system 700. In some embodiments of the disclosure, P-P interface 717 and P-P interface 722 can operate in accordance with a PtP communication protocol, such as the Intel® QuickPath Interconnect (QPI) or the like. In other embodiments, a different interconnect may be used.

In some embodiments, chipset 720 can be configured to communicate with processor 710, the processor N 705, display device 740, and other devices 772, 776, 774, 760, 762, 764, 766, 777, etc. Chipset 720 may also be coupled to the wireless antenna 778 to communicate with any device configured to transmit and/or receive wireless signals.

Chipset 720 connects to display device 740 via interface 726. Display 740 may be, for example, a liquid crystal display (LCD), a plasma display, cathode ray tube (CRT) display, or any other form of visual display device. In some embodiments of the disclosure, processor 710 and chipset 720 are integrated into a single SOC. In addition, chipset 720 connects to bus 750 and/or bus 755 that interconnect various elements 774, 760, 762, 764, and 766. Bus 750 and bus 755 may be interconnected via a bus bridge 772. In one embodiment, chipset 720 couples with a non-volatile memory 760, a mass storage device(s) 762, a keyboard/mouse 764, and a network interface 766 via interface 724 and/or 704, smart TV 776, consumer electronics 777, etc.

In one embodiment, mass storage device(s) 762 can include, but not be limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 or selected elements thereof can be incorporated into processor core 712.

It is noted that the system 700 described herein may be any suitable type of microelectronics packaging and configurations thereof, including, for example, system in a package (SiP), system on a package (SOP), package on package (PoP), interposer package, 3D stacked package, etc. Further, any suitable type of microelectronic components may be provided in the semiconductor packages, as described herein. For example, microcontrollers, microprocessors, baseband processors, digital signal processors, memory dies, field gate arrays, logic gate dies, passive component dies, MEMSs, surface mount devices, application specific integrated circuits, baseband processors, amplifiers, filters, combinations thereof, or the like may be packaged in the semiconductor packages, as disclosed herein. The semiconductor packages (for example, the semiconductor packages described in connection with any of FIGS. 1-6), as disclosed herein, may be provided in any variety of electronic device including consumer, industrial, military, communications, infrastructural, and/or other electronic devices.

In various embodiments, various layers described in connection with the diagrams of the components shown in any of the preceding figures can include, but not be limited to, a metallic, a semi-metallic, or an intermetallic material. In various embodiments, the layers can comprise a metallic material. Non-limiting examples include gold, copper, silver, aluminum, zinc, tin, platinum, and any of the like. Metallic materials may also be any alloys of such materials.

In various embodiments, the layers can comprise a semi-metallic material. Non-limiting examples include arsenic, antimony, bismuth, α-tin (gray tin), graphite, and mercury telluride (HgTe). Semi-metallic materials may also be any mixtures of such materials.

In various embodiments, the layers can comprise an intermetallic material. Non-limiting examples include gold and aluminum intermetallics, copper and tin intermetallics, tin and nickel intermetallics, tin and silver intermetallics, tin and zinc intermetallics, and any of the like. Intermetallic materials may also be any alloys of such materials.

The layers described in connection with the diagrams of the components can be deposited via sputtering, paste printing, squeegee, atomic layer deposition (ALD), or a variety of different physical vapor deposition (PVD) techniques. The layers may be laminated by any suitable process including, for example, cold roll or hot roll. In example embodiments, the layer may be hot pressed at a predetermined temperature and pressure. Additionally the layer can be deposited via any of the above mentioned techniques (or others that are not explicitly named herein) and then picked and placed, laminated thereon, or positioned via any other technique.

The forming of the interconnects comprising metal layers (optionally having a plurality of pads) can further include electrolytic plating metal layers (optionally having a plurality of pads) in the various dielectric buildup layers. In one embodiment, the electroplating can use electrodeposition, for example, using electric current to reduce dissolved metal cations so that they form a coherent metal coating in contact with the metal layers.

In order to fabricate the various build-up, dielectric, and/or metal layers described herein, various fabrication steps can be performed, including steps to laminate the layers, expose the laminated layers to radiation, develop layers, cure the layers, plate the pads into layers, and pattern the layers with the pads embedded therein. In one embodiment, processing the layers can further include exposing the layers using a mask. The mask can include, for example, a photomask, which can refer to an opaque plate with holes or transparencies that allow light to shine through in a defined pattern. In one embodiment, the photomask can include transparent fused silica blanks covered with a pattern defined with a chrome metal-absorbing film. In another embodiment, the photomask can be used at a predetermined wavelength including, but not be limited to, approximately 436 nm, approximately 365 nm, approximately 248 nm, and approximately 193 nm. In one embodiment, there can be a one-to-one correspondence between the mask pattern and the layer pattern, for example, using one-to-one mask aligners. In other embodiments, steppers and scanners with reduction optics can be used to project and shrink the pattern by four or five times onto the surface of the layers. To achieve complete coverage, the dielectric layers are repeatedly “stepped” from position to position under the optical column until full exposure is achieved.

In one embodiment, processing the layers can further include lithographic patterning of the layers using an ultraviolet light source. In one embodiment, the light types that can be used to image the layers can include, but not be limited to, UV and DUV (Deep UV) with the g and I lines having wavelength of approximately 436 nm and approximately 365 nm, respectively, of a mercury-vapor lamp. In various embodiments, the patterning of the layers can include an exposure to the ultraviolet light source for a few seconds through the mask. The areas of the layers which are exposed stay, and the rest of the layers are developed or vice versa.

In one embodiment, the developing light wavelength parameter can be related to the thickness of the layers, with thinner layers corresponding to shorter wavelengths. This can permit a increased aspect ratio and a reduced minimum feature size.

In one embodiment, various chemicals may be used for permanently giving the layers the desired property variations. The chemicals can include, but not be limited to, poly(methyl methacrylate) (PMMA), poly(methyl glutarimide) (PMGI), phenol formaldehyde resin (DNQ/Novolac), and SU-8. In one embodiment, chemicals can be applied as a liquid and, generally, spin-coated to ensure uniformity of thickness.

In one embodiment, processing the layers further comprises curing the layers using a heat source. The heat source can generate heat of a predetermined temperature of approximately 120° C. to approximately 140° C. in approximately 45 minutes. In one embodiment, the heat source can comprise an oven. The oven can have a temperature uniformity of approximately ±0.5% of the predetermined temperature. Moreover, the oven can comprise low particulate environmental controls to protect contamination, for example, using HEPA filtration of the air inside the oven. In one embodiment, the HEPA filter use can produce Class 10 (ISO Class 4) air quality. Moreover, the oven can be configured to have low oxygen levels to prevent oxidation of any of the layers.

It will be appreciated that the apparatus described herein may be any suitable type of microelectronics packaging and configurations thereof, including, for example, system in a package (SIP), system on a package (SOP), package on package (PoP), interposer package, 3D stacked package, etc. In fact, any suitable type of microelectronic components may be provided in connection with the disclosure as described herein. For example, microcontrollers, microprocessors, baseband processors, digital signal processors, memory dies, field gate arrays, memory dies, logic gate dies, passive component dies, MEMSs, surface mount devices, application specific integrated circuits, baseband processors, amplifiers, filters, combinations thereof, or the like may be packaged in the board substrates and/or package substrates as disclosed herein. The components, as disclosed herein, may be provided in any variety of electronic devices, including consumer, industrial, military, communications, infrastructural, and/or other electronic devices.

The components, as described herein, may be used to house one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system, and the one or more processors and any chipsets included in an electronic device may be from a family of Intel® processors and chipsets, such as the Intel® Atom® processor(s) family or Intel-64 processors (for example, Sandy Bridge®, Ivy Bridge®, Haswell®, Broadwell®, Skylake®, etc.). In one embodiment, the components disclosed herein can be co-packaged with other circuits, such as, for example, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof.

Additionally or alternatively, the components, as described herein, may be used in connection with packages having one or more memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR), SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device(s) used in connection with the component are provided may be a computing device. Such a computing device may house one or more boards into which the component may be integrated, for example, integrated into PCB. The board may include a number of components including, but not limited to, a processor and/or at least one communication chip. The processor may be physically and electrically connected to a board through, for example, electrical connections of the component. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

According to example embodiments of the disclosure, there may be a solid assembly. The assembly may comprise: a first termination member having a first end, a second end opposite the first end; a second termination member having a first end, a second end opposite the first end; a coupling element mechanically connected to the first termination member and mechanically connected to the second termination member; a first pad that is at least partially disposed on the first end of the first termination member; and a second pad that is at least partially disposed on the first end of the second termination member.

Implementation may include one or more of the following features. The first termination member and first end of second termination member may be coplanar in the solid assembly. The first termination member may have a first side surface and the second termination member may have a second side surface, and the coupling element may be mechanically connected to the first termination member at the first side surface and the coupling element may be mechanically connected to the second termination member at the second side surface. The coupling element may be mechanically connected to the first termination member at the second end of the first termination member and the coupling element may be mechanically connected to the second termination member at the end of the second termination member. The first and second pads of the solid assembly may comprise a first and second metal pad. A molding layer may at least partially encapsulate the assembly. The solid assembly may further comprise a layer in at least partial contact with the first pad and the second pad, the layer comprising at least one of a permanent resist layer or a non-permanent resist layer. The first pad may form a solder joint to the first termination member and the second pad may form a solider joint to the second termination member.

According to example embodiments of the disclosure, there may be a system. The system may comprise a solid assembly which may comprise: a first termination member having a first end, a second end opposite the first end; a second termination member having a first end, a second end opposite the first end; a coupling element mechanically connected to the first termination member and mechanically connected to the second termination member; a second pad that is at least partially disposed on the first end of the second termination member; and a semiconductor package comprising a redistribution layer (RDL) and one or more metal layers, wherein the RDL is electrically and mechanically coupled to the to the first pad and the second pad at the one or more metal layers.

Implementation may include one or more of the following features. The system may further include a printed circuit board (PCB) having one or more microvias, wherein the solid assembly is embedded in the PCB and is mechanically connected to one or more microvias. The system may further comprise a molding layer that at least partially encapsulates the solid assembly.

According to example embodiments of the disclosure, there may be a method. The method may comprise: forming a metal layer on a carrier layer; forming a resist layer on the metal layer; removing a portion of the resist layer in a first location; forming one or more pads on the resist layer in the first location; connecting the portion of a solid assembly to the one or more pads; and removing the solid assembly including the one or more pads from the carrier layer.

Implementation may include one or more of the following features. Forming the metal layer on the carrier layer may comprise electroplating the metal layer. Connecting the portion of the solid assembly to the one or more pads may comprise soldering at least a portion of the assembly to the one or more pads. Connecting the portion of the solid assembly to the one or more pads may comprise at least one of solder paste printing the on one or more pads or flux dipping the solid assembly. The method may further comprise forming a molding layer to encapsulate at least a portion of the solid assembly. The method may further comprise etching one or more of the metal layer or a portion of the one or more pads after the removing the solid assembly including the one or more pads from the carrier layer. Removing the solid assembly including the one or more pads from the carrier layer may comprise debonding the solid assembly layer, including the one or more pads. Debonding may further comprise reducing an adhesion property of a release layer disposed between the carrier layer and the solid assembly by at least on of i) thermally curing, ii) applying ultraviolet radiation, or iii) applying one or more solvents to the release layer. The method may further comprise forming a passivation layer on the one or more pads. The carrier layer may comprise one or more of a core layer, a prepreg layer, or a second metal layer.

According to example embodiments of the disclosure, there may be a method. The method may comprise forming a metal layer on a carrier layer; removing portions of the metal layer to generate one or more pads; connecting at least a portion of a solid assembly to the one or more pads; and removing the solid assembly including the one or more pads from the carrier layer.

Implementation may include one or more of the following features. Removing portions of the metal layer may further comprise laser cutting the metal layer at one or more predetermined locations. Removing the solid assembly, including the one or more pads from the carrier layer, may further comprise debonding the solid assembly including the one or more pads from the carrier layer. Connecting at least a portion of the solid assembly the one or more pads may comprise at least one of solder paste printing on the one or more pads or flux dipping the solid assembly.

According to example embodiments of the disclosure, there may be an electronic device. The electronic device may comprise a solid assembly which may comprise: a first termination member having a first end, a second end opposite the first end; a second termination member having a first end, a second end opposite the first end; a coupling element mechanically connected to the first termination member and mechanically connected to the second termination member; a first pad that is at least partially disposed on the first end of the first termination member; and a second pad that is at least partially disposed on the first end of the second termination member.

Implementation may include one or more of the following features. The first termination member and first end of second termination member may be coplanar in the solid assembly. The first termination member may have a first side surface and the second termination member may have a second side surface, and the coupling element may be mechanically connected to the first termination member at the first side surface and the coupling element may be mechanically connected to the second termination member at the second side surface. The coupling element may be mechanically connected to the first termination member at the second end of the first termination member and the coupling element may be mechanically connected to the second termination member at the end of the second termination member. The first and second pads of the solid assembly may comprise a first and second metal pad. A molding layer may at least partially encapsulate the assembly. The electronic device comprising the solid assembly may further comprise a layer in at least partial contact with the first pad and the second pad, the layer comprising at least one of a permanent resist layer or a non-permanent resist layer. The first pad may form a solder joint to the first termination member and the second pad may form a solider joint to the second termination member.

According to example embodiments of the disclosure, there may be an electronic device. The electronic device may comprise a system which may comprise: a first termination member having a first end, a second end opposite the first end; a second termination member having a first end, a second end opposite the first end; a coupling element mechanically connected to the first termination member and mechanically connected to the second termination member; a second pad that is at least partially disposed on the first end of the second termination member; and a semiconductor package comprising a redistribution layer (RDL) and one or more metal layers, wherein the RDL is electrically and mechanically coupled to the to the first pad and the second pad at the one or more metal layers.

Implementation may include one or more of the following features. The electronic device may comprise a system which may further include a printed circuit board (PCB) having one or more microvias, wherein the solid assembly is embedded in the PCB and is mechanically connected to one or more microvias. The device may comprise a system which may further comprise a molding layer that at least partially encapsulates the solid assembly.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While the disclosure includes various embodiments, including at least a best mode, it is to be understood that many alternatives, modifications, and variations will be apparent to those skilled in the art, in light of the foregoing description. Accordingly, the disclosure is intended to embrace all such alternatives, modifications, and variations that fall within the scope of the included claims. All matters disclosed herein or shown in the accompanying drawings are to be interpreted in an illustrative and non-limiting sense.

This written description uses examples to disclose certain embodiments of the disclosure, including the best mode, and also to enable any person skilled in the art to practice certain embodiments of the disclosure, including making and using any apparatus, devices, or systems, and performing any incorporated methods and processes. The patentable scope of certain embodiments of the disclosure is defined in the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A solid assembly comprising:
a first termination member having a first end, a second end opposite the first end;
a second termination member having a first end, a second end opposite the first end;
a coupling element mechanically connected to the first termination member and mechanically connected to the second termination member;
a first pad that is at least partially disposed on the first end of the first termination member; and
a second pad that is at least partially disposed on the first end of the second termination member.

2. The solid assembly of claim 1, wherein the first end of the first termination member and the first end of second termination member are coplanar.

3. The solid assembly of claim 1, wherein the first termination member has a first side surface and the second termination member has a second side surface, and the coupling element is mechanically connected to the first termination member at the first side surface and the coupling element is mechanically connected to the second termination member at the second side surface.

4. The solid assembly of claim 1, wherein the coupling element is mechanically connected to the first termination member at the second end of the first termination member and the coupling element is mechanically connected to the second termination member at the end of the second termination member.

5. The solid assembly of claim 1, wherein the first pad comprises a first metal pad, and wherein the second pad comprises a second metal pad.

6. The solid assembly of claim 1, further comprising a molding layer at least partially encapsulating the solid assembly.

7. The solid assembly of claim 1, further comprising a layer in at least partial contact with the first pad and the second pad, the layer comprising at least one of a permanent resist layer or a non-permanent resist layer.

8. The solid assembly of claim 1, wherein the first pad forms a solder joint to the first termination member, and wherein the second pad forms a solder joint to the second termination member.

9. A system, comprising:
a solid assembly, comprising:
a first termination member having a first end, a second end opposite the first end;
a second termination member having a first end, a second end opposite the first end;
a coupling element mechanically connected to the first termination member and mechanically connected to the second termination member;
a first pad that is at least partially disposed on the first end of the first termination member; and
a second pad that is at least partially disposed on the first end of the second termination member; and
a semiconductor package comprising a redistribution layer (RDL) and one or more metal layers, wherein the RDL is electrically and mechanically coupled to the to the first pad and the second pad at the one or more metal layers.

10. The system of claim 9, further including a printed circuit board (PCB) having one or more microvias, wherein the solid assembly is embedded in the PCB and is mechanically connected to one or more microvias.

11. The system of claim 9, further comprising a molding layer that at least partially encapsulates the solid assembly.

12. A method, comprising:
forming a metal layer on a carrier layer;
forming a resist layer on the metal layer;
removing a portion of the resist layer in a first location;
forming one or more pads on the resist layer in the first location;
connecting the portion of a solid assembly to the one or more pads; and
removing the solid assembly including the one or more pads from the carrier layer.

13. The method of claim 12, wherein forming the metal layer on the carrier layer comprises electroplating the metal layer.

14. The method of claim 12, wherein connecting the portion of the solid assembly to the one or more pads comprises soldering at least a portion of the solid assembly to the one or more pads.

15. The method of claim 12, wherein connecting the portion of the solid assembly to the one or more pads comprises at least one of solder paste printing the on one or more pads or flux dipping the solid assembly.

16. The method of claim 12, the method further comprising forming a molding layer to encapsulate at least a portion of the solid assembly.

17. The method of claim 12, the method further comprising etching one or more of the metal layer or a portion of the one or more pads after the removing the solid assembly including the one or more pads from the carrier layer.

18. The method of claim 12, wherein removing the solid assembly including the one or more pads from the carrier layer comprises debonding the solid assembly including the one or more pads from the carrier layer.

19. The method of claim 18, wherein debonding the solid assembly including the one or more pads from the carrier layer further comprises reducing an adhesion property of a release layer disposed between the carrier layer and the solid assembly by at least on of i) thermally curing, ii) applying ultraviolet radiation, or iii) applying one or more solvents to the release layer.

20. The method of claim 12, further comprising forming a passivation layer on the one or more pads.

21. The method of claim 12, wherein the carrier layer comprises one or more of a core layer, a prepreg layer, or a second metal layer.

22. A method, comprising:
forming a metal layer on a carrier layer;
removing portions of the metal layer to generate one or more pads;
connecting at least a portion of a solid assembly to the one or more pads; and
removing the solid assembly including the one or more pads from the carrier layer.

23. The method of claim 22, wherein the removing portions of the metal layer further comprises laser cutting the metal layer at one or more predetermined locations.

24. The method of claim 22, wherein removing the solid assembly including the one or more pads from the carrier layer further comprises debonding the solid assembly including the one or more pads from the carrier layer.

25. The method of claim 22, wherein connecting the at least a portion of the solid assembly to the one or more pads further at least one of solder paste printing on the one or more pads or flux dipping the solid assembly.

26. An electronic device, comprising:
a solid assembly, the assembly comprising:
a first termination member having a first end, a second end opposite the first end;
a second termination member having a first end, a second end opposite the first end;
a coupling element mechanically connected to the first termination member and mechanically connected to the second termination member;
a first pad that is at least partially disposed on the first end of the first termination member; and
a second pad that is at least partially disposed on the first end of the second termination member; and
at least one electronic component electronically coupled to the solid assembly by one or more of the first pad or the second pad.

27. The electronic device of claim 26, wherein the first end of the first termination member and the first end of second termination member are coplanar.

28. The electronic device of claim 26, wherein the first termination member has a first side surface and the second termination member has a second side surface, and the coupling element is mechanically connected to the first termination member at the first side surface and the coupling element is mechanically connected to the second termination member at the second side surface.

29. The electronic device of claim 26, wherein the coupling element is mechanically connected to the first termination member at the second end of the first termination member and the coupling element is mechanically connected to the second termination member at the end of the second termination member.

30. The electronic device of claim 26, wherein the first pad comprises a first metal pad, and wherein the second pad comprises a second metal pad.

31. The electronic device of claim 26, further comprising a molding layer at least partially encapsulating the solid assembly.

32. The electronic device of claim 26, further comprising a layer in at least partial contact with the first pad and the second pad, the layer comprising at least one of a permanent resist layer or a non-permanent resist layer.

33. The electronic device of claim 26, wherein the first pad forms a solder joint to the first termination member, and wherein the second pad forms a solder joint to the second termination member.

34. An electronic device, comprising:
a solid assembly, comprising:
a first termination member having a first end, a second end opposite the first end;
a second termination member having a first end, a second end opposite the first end;
a coupling element mechanically connected to the first termination member and mechanically connected to the second termination member;
a first pad that is at least partially disposed on the first end of the first termination member; and
a second pad that is at least partially disposed on the first end of the second termination member; and
a semiconductor package comprising a redistribution layer (RDL) and one or more metal layers, wherein the RDL is electrically and mechanically coupled to the to the first pad and the second pad at the one or more metal layers.

35. The electronic device of claim 34, further including a printed circuit board (PCB) having one or more microvias, wherein the solid assembly is embedded in the PCB and is mechanically connected to one or more microvias.

36. The electronic device of claim 34, further comprising a molding layer that at least partially encapsulates the solid assembly.
